(19) United States
(12) Patent Application Publication
(10) Pub. No.: US 2017/0077925 A1
(43) Pub. Date: Mar. 16, 2017

(54) SEMICONDUCTOR DEVICE

(71) Applicant: Kabushiki Kaisha Toshiba, Tokyo (JP)

(72) Inventor: Toshiyuki Naka, Nonoichi Ishikawa (JP)

(21) Appl. No.: 15/063,634

(22) Filed: Mar. 8, 2016

(30) Foreign Application Priority Data
Sep. 11, 2015 (JP) 2015-180011

(51) Int. Cl. H03K 17/693; H01L 29/20

(52) U.S. Cl. CPC H03K 17/693; H01L 29/2003

(57) ABSTRACT

According to embodiments, a semiconductor device includes a field-effect transistor; a switch; and a controller. The field-effect transistor includes a substrate; a nitride semiconductor layer on the substrate; a drain electrode and a source electrode on the nitride semiconductor layer; and a gate electrode between the drain electrode and the source electrode. The switch switches a potential of the substrate to a plurality of potentials. The controller controls the switch so as to set one potential among the plurality of potentials based on an input to the drain electrode.

### CROSS-REFERENCE TO RELATED APPLICATIONS

This application is based upon and claims the benefit of priority from Japanese Patent Application No. 2015-180011, filed on Sep. 11, 2015; the entire contents of which are incorporated herein by reference.

### FIELD

The embodiments of the present invention relate to a semiconductor device, a drive control device, and a drive control method.

### BACKGROUND

A field-effect transistor comprising nitride semiconductor layers is known as one example of semiconductor devices. This field-effect transistor comprises, for example, a substrate and at least two nitride semiconductor layers. The bandgaps of these nitride semiconductor layers differ from each other. As a result, current pathways (channels) called as two-dimensional electron gases are formed in the interfacial boundaries of these nitride semiconductor layers.

In the above-described field-effect transistor, a so-called current collapse phenomenon in which the density of a two-dimensional electron gas decreases and ON-resistance increases may occur. The current collapse phenomenon is considered to depend on a substrate potential and a drain voltage.

In general, a destination of electrical connection of the substrate is set before the field-effect transistor is driven. Accordingly, the potential of the substrate is always fixed irrespective of the drain voltage when the field-effect transistor is driven. As a result, the optimization of the substrate potential against the current collapse phenomenon is insufficient.

The embodiments of the present invention provide a semiconductor device, a drive control device and a drive control method capable of optimizing the substrate potential against the current collapse phenomena

### BRIEF DESCRIPTION OF THE DRAWINGS

FIG. 1 is a circuit diagram illustrating the schematic configuration of a semiconductor device according to a first embodiment;

FIG. 2 is a cross-sectional view illustrating the schematic structure of a field-effect transistor illustrated in FIG. 1;

FIG. 3 is a drawing illustrating one example of data stored in a controller illustrated in FIG. 1;

FIG. 4 is a graph illustrating one example of a relationship between an input voltage and the rate of increase in ON-resistance;

FIG. 5 is a flowchart illustrating the operating procedure of the semiconductor device according to the first embodiment;

FIG. 6 is a drawing illustrating a modified example of a switch capable of switching the potential of a substrate;

FIG. 7 is a circuit diagram illustrating the schematic configuration of a semiconductor device according to a second embodiment; and

FIG. 8 is a flowchart illustrating the operating procedure of the semiconductor device according to the second embodiment.

### DETAILED DESCRIPTION

Embodiments will now be explained with reference to the accompanying drawings. The present invention is not limited to the embodiments.

### First Embodiment

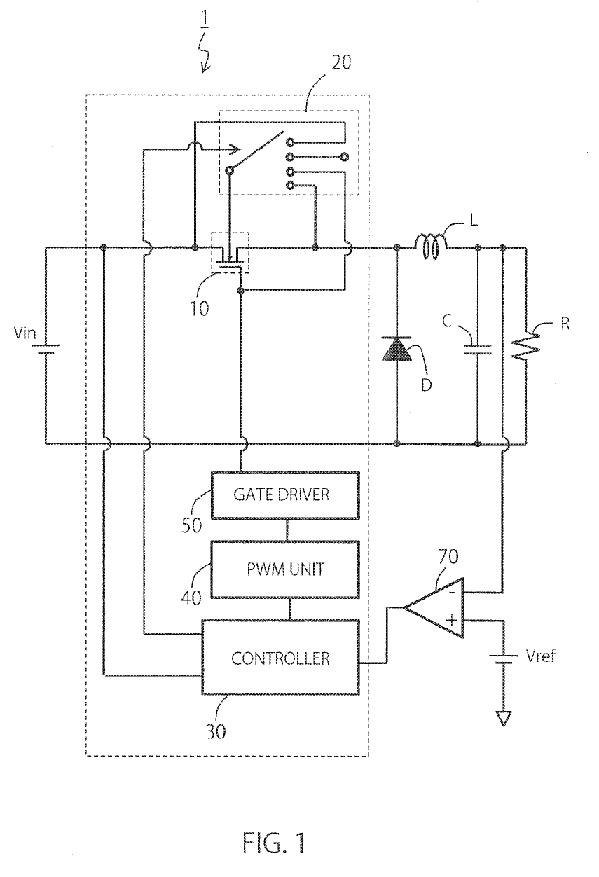

FIG. 1 is a circuit diagram illustrating the schematic configuration of a semiconductor device according to a first embodiment. Note that FIG. 1 also shows a diode D, a coil L, a capacitor C and a resistance load R in addition to a semiconductor device 1 according to the present embodiment. These components are external components when the semiconductor device 1 according to the present embodiment is applied to a back converter.

A comparator 70 illustrated in FIG. 1 is also an external component to detect whether or not the output voltage of the back converter is lower than a reference voltage Vref. These external components will not be described in detail here, but the configuration of the semiconductor device 1 according to the present embodiment will be described hereinafter.

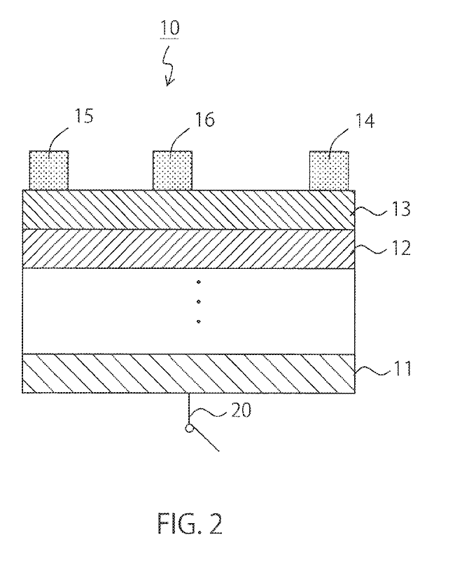

As illustrated in FIG. 1, the semiconductor device 1 according to the present embodiment comprises a field-effect transistor 10; a switch 20; a controller 30; a PWM (Pulse Width Modulation) unit 40; and a gate driver 50. First, the structure of the field-effect transistor 10 will be described with reference to FIG. 2.

FIG. 2 is a cross-sectional view illustrating the schematic structure of the field-effect transistor 10. As illustrated in FIG. 2, the field-effect transistor 10 comprises a substrate 11, a first nitride semiconductor layer 12, a second nitride semiconductor layer 13, a drain electrode 14, a source electrode 15, and a gate electrode 16.

The substrate 11 is composed of a conductive substrate, such as a silicon substrate. A plurality of nitride semiconductor layers including the first nitride semiconductor layer 12 and the second nitride semiconductor layer 13 are provided on the substrate 11. The switch 20 is connected to the back surface of the substrate 11, in other words, a surface on the opposite side of a surface on which the first nitride semiconductor layer 12 and the second nitride semiconductor layer 13 are disposed.

The first nitride semiconductor layer 12 is composed of, for example, gallium nitride (GaN). The second nitride semiconductor layer 13 is provided on the first nitride semiconductor layer 12.

The second nitride semiconductor layer 13 is composed of, for example, aluminum nitride gallium (AlGaN), wherein a bandgap of the than second nitride semiconductor layer 13 is larger than that of the first nitride semiconductor layer 12. A two-dimensional electron gas is generated in an interfacial boundary between the first nitride semiconductor layer 12 and the second nitride semiconductor layer 13.

The drain electrode 14, the source electrode 15 and the gate electrode 16 are provided on the second nitride semiconductor layer 13. The gate electrode 16 is sandwiched between the drain electrode 14 and the source electrode 15 on the second nitride. semiconductor layer 13.

Next, the switch 20 will be described by referring back to FIG. 1. The switch 20 can switch the potential of the substrate 11 to a plurality of potentials. In the present embodiment, the switch 20 can switch the potential to a first state in which the substrate 11 is electrically connected to the source electrode 15, a second state in which the substrate 11 is electrically connected to the drain electrode 14, a third state in which the substrate 11 is electrically connected to the gate electrode 16, and a fourth state in which the substrate 11 is made electrically open. That is, the potential of the substrate 11 is the same as the potential of the source electrode 15 in the first state, the potential of the substrate 11 is the same as the potential of the drain electrode 14 in the second state, the potential of the substrate 11 is the same as the potential of the gate electrode 16 in the third state, and the potential of the substrate 11 is the same as a floating potential in the fourth state.

Note that the field-effect transistor 10 is a normally-on type field-effect transistor in the present embodiment, and therefore, the potential of the substrate 11 is a negative potential in the third state.

The controller 30 constitutes a drive control device for the field-effect transistor 10 with the switch 20. The controller 30 stores data that correlates the states of the switch 20 used to set the potential of the substrate 11 with an input voltage Vin to be input to the drain electrode 14.

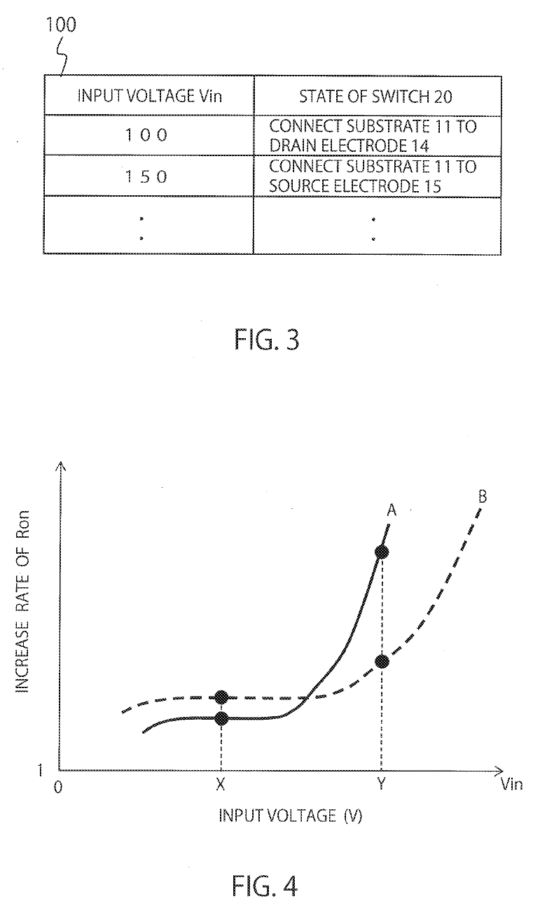

FIG. 3 is a drawing illustrating one example of the data stored in the controller 30. FIG. 4 is a graph illustrating one example of the relationship between the input voltage and the rate of increase in ON-resistance.

In FIG. 4, the axis of abscissas represents a voltage input to the drain electrode 14, in other words, a drain-source voltage, whereas the axis of ordinates represents the rate of increase in ON-resistance (Ron). A solid line A represents the rate of increase in ON-resistance of the second state in which the substrate 11 is electrically connected to the drain electrode 14, whereas a dotted line B represents that of the first state in which the substrate 11 is electrically connected to the source electrode 15.

According to FIG. 4, when the input voltage is X, the rate of increase in ON-resistance of the second state is less than that of the first state. On the other hand, when the input voltage is Y (Y>X), the rate of increase in ON-resistance of the first state is less than that of the second state. Accordingly, when the input voltage is X, the switch 20 preferably connects the substrate 11 to the drain electrode 14. Alternatively, when the input voltage is Y, the switch 20 preferably connects the substrate 11 to the source electrode 15.

Hence, the optimum state of the switch 20 according to the value of the input voltage, in other words, a potential of the substrate 11 optimized against a current collapse phenomenon is presented in data 100 illustrated in FIG. 3. In this way, the controller 30 selects the optimum potential of the substrate 11 from the data 100 based on the value of the input voltage.

Note that even if the axis of abscissas represents an input current input to the drain electrode 14 in the graph illustrated in FIG. 4, the relationship between the input current and the ON-resistance is the same as the relationship between the input voltage and the ON-resistance. The values of the input current may therefore be shown in the data 100 in association with the states of the switch 20. Even in this case, the controller 30 can select the optimum potential of the substrate 11 based on the value of the input current.

The controller 30 also controls the PWM unit 40 based on a previously-stored predetermined program. The PWM unit 40 will be described here by referring back again to FIG. 1. The PWM unit 40 generates and outputs a PWM signal to the gate driver 50. The gate driver 50 drives the gate of the field-effect transistor 10 based on the PWM signal input from the PWM unit 40. Note that although the PWM unit 40 and the gate driver 50 are built in the semiconductor device 1 in the present embodiment, these components may be disposed externally to the semiconductor device 1.

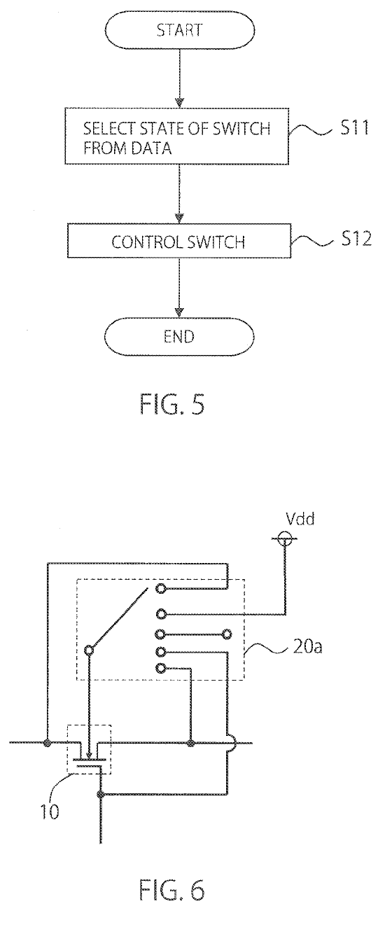

Hereinafter, a description will be made of the operation of the semiconductor device 1 according to the present embodiment. FIG. 5 is a flowchart illustrating the operating procedure of the semiconductor device 1 according to the present embodiment. Here, a description will be made of operations used to select the potentials of the substrate 11.

When the potential of the drain electrode 14 of the semiconductor device 1 rises from 0 V to the value of the input voltage Vin, the controller 30 selects a state of the switch 20 corresponding to the value of the input voltage Vin from the data 100 (step S11).

Subsequently, the controller 30 controls the switch 20 so as to set the state selected in step S11 (step S12). In step S12, for example, if the switch 20 is composed of four transistors corresponding to the four states (first to fourth states) of the substrate 11, the controller 30 turns on a transistor corresponding to the selected state and turns off the remaining transistors.

According to the above-described semiconductor device 1 of the present embodiment, the controller 30 controls the switch 20 capable of switching the potential of the substrate 11 based on the data 100. For each input voltage, the data 100 shows a state of the switch 20 to set the potential of the substrate 11 to a potential optimum against a current collapse phenomenon. Consequently, it is possible to optimize the potential of the substrate 11 based on the input voltage.

Note that the states of the substrate 11 that can be switched by the switch 20 are not limited to the above-described four states. FIG. 6 is a drawing illustrating a modified example of the switch capable of switching the potential of the substrate 11.

A switch 20a illustrated in FIG. 6 can switch the potential of the substrate 11 to not only the above-described first to fourth states but also a fifth state in which the substrate 11 is connected to a constant-voltage source Vdd. According to this switch 20a, the potential of the substrate 11 can be optimized against a current collapse phenomenon by allowing the controller 30 to control the switch 20a, if there is any input voltage at which ON-resistance is smallest when the potential of the substrate 11 equals the potential of the constant-voltage source Vdd.

### Second Embodiment

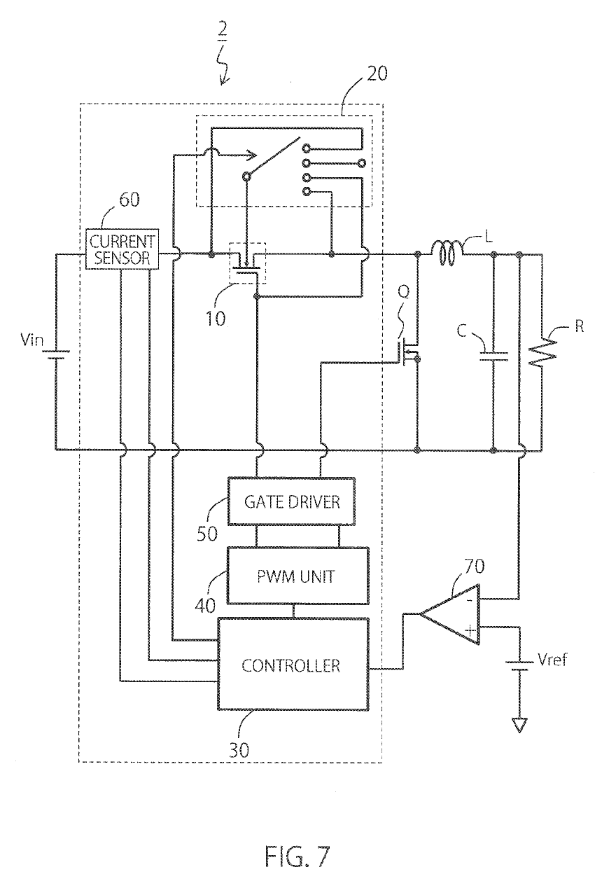

FIG. 7 is a circuit diagram illustrating the schematic configuration of a semiconductor device according to a second embodiment. An N-type MOS transistor Q composed of a silicon semiconductor, a coil L, a capacitor C, and a resistance load R are also illustrated in FIG. 7. These components are external components when a semiconductor device 2 according to the present embodiment is applied to a back converter.

A comparator 70 illustrated in FIG. 7 is also an external component used to detect whether or not the output voltage of the back converter is lower than the reference voltage Vref, as in the first embodiment. These external components will not be described in detail here, but the configuration of the semiconductor device 2 according to the present embodiment will be described hereinafter with a focus on differences from the semiconductor device 1 according to the first embodiment.

As illustrated in FIG. 7, the semiconductor device 2 of the present embodiment differs from the semiconductor device 1 of the first embodiment in that the semiconductor device 2 comprises a current sensor 60. The current sensor 60 measures an input current input to the drain electrode 14 as controlled by the controller 30.

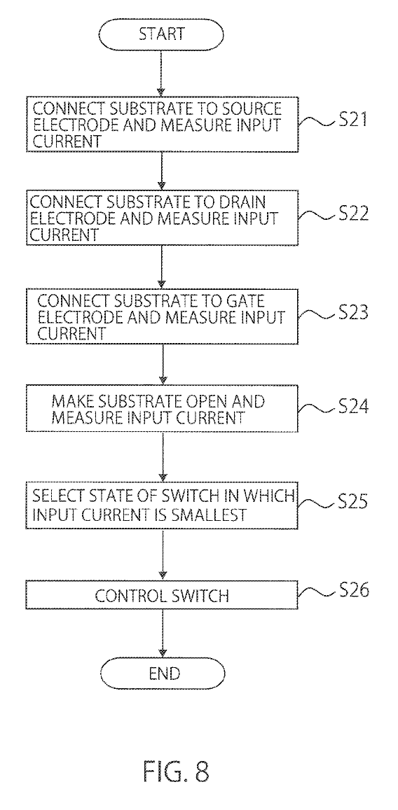

Hereinafter, a description will be made of the operation of the semiconductor device 2 according to the present embodiment. FIG. 8 is a flowchart illustrating the operating procedure of the semiconductor device 2 according to the present embodiment. A description will also be made here of operations used to select the potentials of the substrate 11, as in the first embodiment.

When the potential of the drain electrode 14 of the semiconductor device 2 rises from 0 V to the value of the input voltage Vin, the controller 30 controls the switch 20, so that the substrate 11 is electrically connected to the source electrode 15. Thereafter; the current sensor 60 measures the input current (step S21).

Subsequently, the controller 30 controls the switch 20, so that the substrate 11 is electrically connected to the drain electrode 14. Thereafter, the current sensor 60 measures the input current (step S22).

Next, the controller 30 controls the switch 20, so that the substrate 11 is electrically connected to the gate electrode 16. Thereafter, the current sensor 60 measures the input current (step S23).

Subsequently, the controller 30 controls the switch 20, so that the substrate 11 is made electrically open. Thereafter, the current sensor 60 measures the input current (step S24).

In steps S21 to S24 described above, the controller 30 sets the potential of the substrate 11 to the potential of the source electrode 15, the potential of the drain electrode 14, the potential of the gate electrode 16, and the floating potential in this order. This order is not limited in particular, but may be changed as appropriate.

Also in step S21 to S24 described above, the measured values of the current sensor 60 are stored in the controller 30. The controller 30 selects a state of the switch 20 in which the input current is smallest among the stored measured values (step S25).

The flowchart indicates that ON-resistance becomes lower with a decrease in the input current if the input voltages in steps S21 to S24 are the same in the field-effect transistor 10. That is, the state of the switch 20 in which the input current is smallest corresponds to the potential of the substrate 11 optimum against a current collapse phenomenon. Hence, the controller 30 controls the switch 20 so as to set the state selected in step S25 (step S26).

According to the above-described semiconductor device 2 of the present embodiment, the controller 30 controls the switch 20 capable of switching the potential of the substrate 11 based on the measured values of the current sensor 60. The current sensor 60 measures the input current for every potential that the substrate 11 can have, whereas the controller 30 selects a state of the switch 20 in which the input current is smallest among the measured values of the current sensor 60. The selected state corresponds to the potential of the substrate 11 optimum against a current collapse phenomenon, as described above. Consequently, it is possible to optimize the potential of the substrate 11 according to the input voltage.

In particular, in the present embodiment, the input current is measured for every potential that the substrate 11 can have, each time the input voltage Vin is supplied to the drain electrode 14 of the field-effect transistor 10. Then, a potential of the substrate 11 optimum against a current collapse phenomenon is selected based on the result of this measurement. Accordingly, it is possible to promptly select the optimum potential of the substrate 11 when, for example, the input voltage Vin varies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a field-effect transistor including a substrate, a first nitride semiconductor layer on the substrate, a second nitride semiconductor layer on the first nitride semiconductor layer, wherein a bandgap of the second nitride semiconductor layer is larger than that of the first nitride semiconductor layer, a drain electrode and a source electrode on the second nitride semiconductor layer, and a gate electrode between the drain electrode and the source electrode, wherein a two-dimensional electron gas is generated between the first nitride semiconductor layer and the second nitride semiconductor layer;
a switch that switches a potential of the substrate to a plurality of potentials; and
a controller that controls the switch so as to set the potential of the substrate which results the minimum ON-resistance of the field-effect transistor among the plurality of potentials based on an input to the drain electrode.

2. The semiconductor device according to claim 1, wherein the switch switches the potential of the substrate to a first state in which the substrate is electrically connected to the source electrode, a second state in which the substrate is electrically connected to the drain electrode, a third state in which the substrate is electrically connected to the gate electrode, and a fourth state in which the substrate is electrically open.

3. The semiconductor device according to claim 1, wherein the controller stores data that correlates a state of the switch corresponding to one of the plurality of potentials with the input value of the drain electrode, and controls the switch based on the data.

4. The semiconductor device according to claim 1, further comprising a current sensor that measures the input current of the drain electrode in each of the plurality of potentials as controlled by the controller,
wherein the controller controls the switch to set a potential in which the input current measured by the current sensor is smallest.

5. The semiconductor device according to claim 2, wherein the switch also switches the state of the substrate to a fifth state in which the substrate is electrically connected to a constant-voltage source.

6. The semiconductor device according to claim 1, wherein the switch is connected to the back surface of the substrate.

7. (canceled)

8. A drive control device of a field-effect transistor including a substrate, a first nitride semiconductor layer on the substrate, a second nitride semiconductor layer on the first nitride semiconductor layer, wherein a bandgap of the second nitride semiconductor layer is larger than that of the first nitride semiconductor layer, a drain electrode and a source electrode on the nitride semiconductor layer, and a gate electrode between the drain electrode and the source electrode, wherein a two-dimensional electron gas is generated between the first nitride semiconductor layer and the second nitride semiconductor layer the drive control device comprising:
a switch that switches a potential of the substrate to a plurality of potentials; and
a controller that controls the switch so as to set the potential of the substrate which results the minimum ON-resistance of the field-effect transistor among the plurality of potentials based on an input to the drain electrode.

9. The drive control device according to claim 8, wherein the switch switches the potential of the substrate to a first state in which the substrate is electrically connected to the source electrode, a second state in which the substrate is electrically connected to the drain electrode, a third state in which the substrate is electrically connected to the gate electrode, and a fourth state in which the substrate is electrically open.

10. The drive control device according to claim 8, wherein the controller stores data that correlates a state of the switch corresponding to one of the plurality of potentials with the input value of the drain electrode, and controls the switch based on the data.

11. The drive control device according to claim 9, wherein the switch also switches the state of the substrate to a fifth state in which the substrate is electrically connected to a constant-voltage source.

12. A drive control method of a field-effect transistor comprising a substrate, a first nitride semiconductor layer on the substrate, a second nitride semiconductor layer on the first nitride semiconductor layer, wherein a bandgap of the second nitride semiconductor layer is larger than that of the first nitride semiconductor layer, a drain electrode and a source electrode on the nitride semiconductor layer, and a gate electrode between the drain electrode and the source electrode, wherein a two-dimensional electron gas is generated between the first nitride semiconductor layer and the second nitride semiconductor layer, the method comprising the steps of:
selecting a state of a switch that switches the potential of the substrate to result the minimum ON-resistance of the field-effect transistor among a plurality of potentials based on an input to the drain electrode; and
controlling the switch so as to set the state selected in the step of selecting the state of the switch.
